(19) United States
(12) Patent Application Publication
(10) Pub. No.: US 2011/0062569 A1
(43) Pub. Date: Mar. 17, 2011

(54) SEMICONDUCTOR DEVICE PACKAGE WITH DOWN-SET LEADS

(75) Inventors: Kai Yun Yow, Petaling Jaya (MY); Poh Leng Eu, Petaling Jaya (MY)

(73) Assignee: FREESCALE SEMICONDUCTOR, INC, Austin, TX (US)

(21) Appl. No.: 12/577,730

(22) Filed: Oct. 13, 2009

(30) Foreign Application Priority Data
Sep. 14, 2009 (MY) PI20093809

(51) Int. Cl. H01L 23/495; H01L 21/60

(52) U.S. Cl. 257/676; 438/123; 257/E23.031; 257/E21.506

(57) ABSTRACT

A QFP type packaged device includes down-set leads to allow for more I/O's and a smaller foot print. The device includes a die attached to a flag of a lead frame. Die pads are electrically connected to leads of the lead frame with wires. The leads are bent and include indentations so that they are exposed at the bottom side of the package. The leads are also trimmed so that they do not extend out of the sides of the packaged device.

### BACKGROUND OF THE INVENTION

The present invention relates generally to semiconductor device packaging, and more particularly to a packaged semiconductor device with down-set leads.

There is a continuous drive to make electrical appliances such as computers, televisions, stereos, cell phones, etc. smaller, which drives the need for more highly integrated semiconductor devices in smaller packages. That is, there is a need for semiconductor devices with smaller foot prints. One type of semiconductor package is known as a Quad Flat Pack (QFP). FIG. 1 is a side cross-sectional view of a QFP device 10. The QFP device 10 includes a semiconductor die 12, which is an integrated circuit formed in Silicon, attached to a flag 14 of a lead frame with epoxy 16. The die 12 is electrically connected to leads 18 with wires 20, typically via a wire bonding process. The die 12, flag 14, wires 20 and part of the leads 18 are encapsulated with a plastic mold compound 22 for protecting the die 12 and wires 20. The leads 18 are bent and extend out of the sides of the mold compound 22. The leads 18 allow the QFP device 10 to be attached to a printed circuit board (not shown) for connection to other devices. The size or foot print of the device is show with line A-A.

FIG. 2 is a top plan view of the QFP device 10 prior to encapsulation with the mold compound 22. As can be seen, the die 12 is attached to the flag 14, and electrically connected to the leads 18 with the wires 20. Such QFP devices are well known and commonly available from many semiconductor device manufacturers.

It would be advantageous to have more I/O's (inputs and outputs) available to accommodate more complex integrated circuits. It would also be advantageous to have more leads in a smaller device foot print.

### BRIEF DESCRIPTION OF THE DRAWINGS

The invention, together with objects and advantages thereof, may best be understood by reference to the following description of the presently preferred embodiments together with the accompanying drawings. In the drawings, like numerals are used for like elements throughout.

FIG. 1 is an enlarged cross-sectional side view of a conventional QFP device;

FIG. 2 is top plan view of the QFP device shown in FIG. 1;

FIG. 3 is an enlarged cross-sectional side view of a semiconductor device in accordance with an embodiment of the present invention;

FIG. 4 is an enlarged top plan view of an alternate embodiment of the semiconductor device shown in FIG. 3;

FIG. 5 is an enlarged bottom plan view of the semiconductor device shown in FIG. 4; and

FIGS. 6-10 are enlarged cross-sectional side views of semiconductor devices in accordance with other alternative embodiments of the present invention.

### DETAILED DESCRIPTION OF THE INVENTION

In one embodiment, the present invention provides a semiconductor device including a die, a lead frame and a mold compound. The semiconductor die includes an integrated circuit formed therein and a plurality of wire bonding pads that allow for connectivity to the integrated circuit. The lead frame includes a plurality of leads, each of the plurality of leads having a first end and a second end. Respective ones of the wire bonding pads are electrically connected to corresponding ones of the leads at the first ends of the leads. The mold compound encapsulates the die, the leads, and the electrical connections between the leads and the wire bonding pads.

The second ends of the leads extend beyond the mold compound such that they are exposed. The leads comprise a strip of conductive material having a first downward bend proximate to the first end, a second bend proximate to the second end such that the strip after the second bend is substantially parallel with the strip prior to the first bend. A micro-indentation is made between the second bend and the second end. The micro-indentation causes a bottom surface of the lead to be exposed through a bottom surface of the mold compound.

In another embodiment, the present invention provides a lead frame for a Quad Flat Pack (QFP) type semiconductor device, comprising a plurality of leads, each lead having a first end and a second end. The leads extend outwardly from a generally rectangular central space with the first ends being proximate to the central space and the second ends being distal from the central space. Each lead comprises a strip of conductive material having a first downward bend proximate to the first end, a second bend proximate to the second end such that the strip after the second bend is substantially parallel with the strip prior to the first bend, and a micro-indentation between the second bend and the second end. The micro-indentation defines a downwardly projecting dimple.

The present invention also provides a method of assembling a semiconductor device, including the steps of:

providing a lead frame having a plurality of leads, each lead having a first end and a second end, wherein the leads extend outwardly from a generally rectangular central space, the first ends being proximate to the central space and the second ends being distal from the central space, and

wherein each lead comprises a strip of conductive material having a first downward bend proximate to the first end, a second bend proximate to the second end such that the strip after the second bend is substantially parallel with the strip prior to the first bend, and a micro-indentation between the second bend and the second end, the micro-indentation defining a downwardly projecting dimple;

providing a semiconductor die having an integrated circuit therein;

electrically connecting the leads to the integrated circuit; and

encapsulating the semiconductor die, the electrical connections and the leads with a mold compound, wherein the second ends of the leads protrude from the sides of the mold compound and a bottom surface of the leads at the dimple is exposed at a bottom surface of the mold compound.

Referring now to FIG. 3, an enlarged, cross-sectional side view of semiconductor device 30 is shown. The semiconductor device 30 includes a semiconductor die 32 including an integrated circuit (IC) formed therein and a plurality of wire bonding pads that allow for connectivity to the IC. Such semiconductor die and integrated circuits are well known by those of skill in the art and further description of the die or IC is not necessary for a complete understanding of the invention.

The semiconductor device 30 also includes a lead frame including a plurality of leads 34 (two of which are shown in FIG. 3). Each of the plurality of leads 34 has a first end 36 and a second end 38. Respective ones of the wire bonding pads are electrically connected to corresponding ones of the leads 34 at the first ends 36 thereof. The leads 34 may be connected to the wire bonding pads with wires 40 using known wire bonding technology.

In the embodiment shown, the lead frame includes a flag 42. The semiconductor die 32 may be attached to the flag 42 with epoxy 44, but other methods of attachment could also be used, such as with tape, as is known in the art. The bottom or non-active surface of the die 32 is attached to the flag 42.

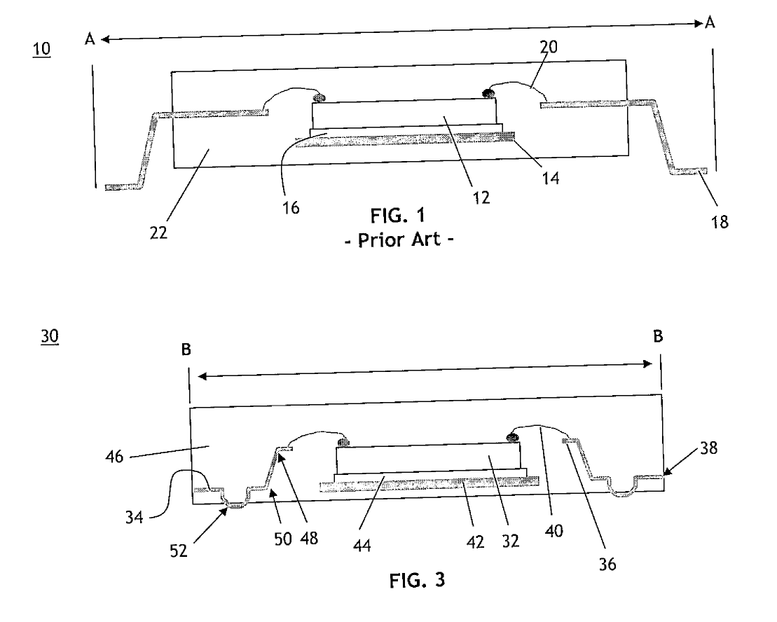

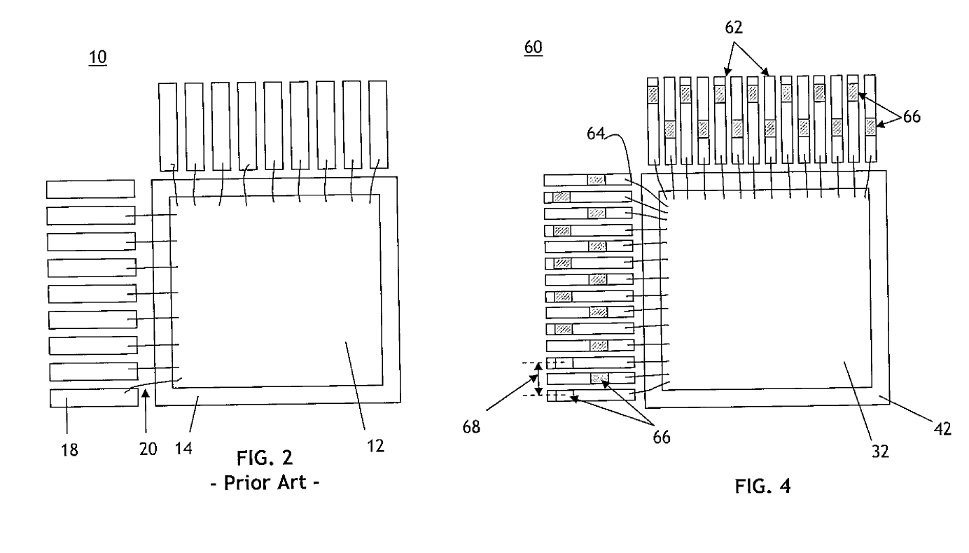

A mold compound 46 encapsulates the die 32, the leads 34, and the electrical connections between the leads 34 and the wire bonding pads. The second ends 38 of the leads extend beyond the mold compound 46 such that the second ends 38 of the leads are exposed. In the embodiment shown, the second ends 38 of the leads have been trimmed so that the leads 34 do not protrude from the mold compound 46. Trimming the leads 34 prevents problems encountered by leads that protrude such as those shown in FIG. 1, namely problems caused by bent leads.

The lead frame is formed of a conductive material, such as copper foil and may be bare or plated with another material such as Tin, Nickel, Palladium, or Gold. Typically a plurality of lead frames is formed from a sheet of copper foil by cutting, punching, stamping or combinations of these processes. Such lead frame production is well known by those of skill in the art.

The leads 34 comprise a strip of conductive material (e.g., copper as described above) having a first downward bend 48 proximate to the first end 36. In this case, downward means toward the bottom surface of the die 32 or bottom of the semiconductor device 30. The bend need not be 90°, but instead can range from about 90° to about 130°. The leads 34 have a second bend 50 proximate to the second end 38 such that the strip after the second bend 50 is substantially parallel with the strip prior to the first bend 48. The angle to form the second bend 50 depends on the angle of the first bend 48. In one embodiment, a distance from the first bend 48 to the first end 36 is about 1.0 mm, and a distance from the second bend 50 to the second end 38 is about 3.0 mm.

A dimple, indent or micro-indentation 52 is formed between the second bend 50 and the second end 38. The micro-indentation 52 causes a bottom surface of the lead 34 to be exposed and slightly protrude through a bottom surface of the mold compound 46 for electrical contact. Since the leads 34 do not extend well outside of the mold compound 46 as they do in the conventional device package (FIG. 1), the device 30 has a smaller overall foot print, as indicated with line B-B, as compared to line A-A of FIG. 1. Thus, the embodiment shown provides a Quad Flat Pack (QFP) type packaged device that has a smaller foot print and will not encounter problems that may arise from bent leads.

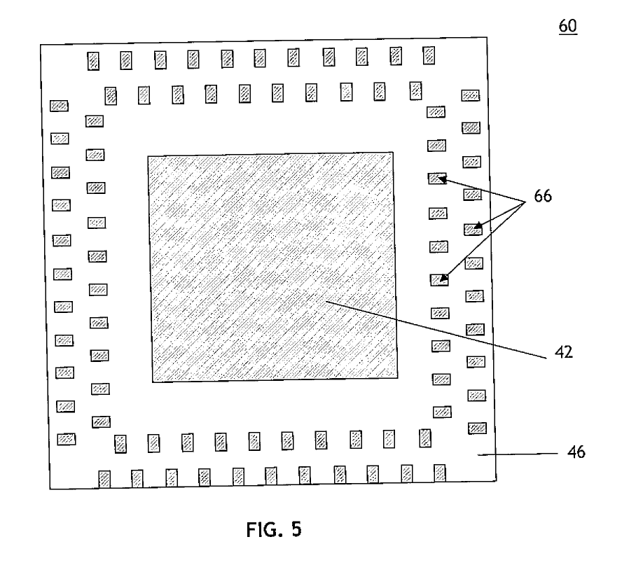

Referring now to FIGS. 4 and 5, another embodiment of a semiconductor device 60 in accordance with the present invention is shown, where FIG. 4 is a top plan view of the semiconductor device 60 and FIG. 5 is a bottom plan view of the device 60. In FIG. 4, the device 60 is shown prior to encapsulation with the mold compound 46 and FIG. 5 shows the device 60 after encapsulation. The semiconductor device 60 includes the die 32 and flag 42 shown in the embodiment of FIG. 3. Wire bond pads (not specifically illustrated) are electrically connected to leads 62 with wires 64 using a known wire bonding process, as discussed above with reference to FIG. 3. Thus, the device 60 is similar to the device 30 shown in FIG. 3 except that micro-indentations 66 on the leads 62 are formed either closer or further from a second or outer end of the lead 62 for alternate leads. That is, for alternate leads 62, the micro-indentations 66 are located closer to the second bend (bend 50 in FIG. 3) such that a pair of rows of the exposed bottom surfaces of the leads 62 is formed at the bottom surface of the mold compound 46 (see FIG. 5). It should be noted that for ease of illustration, the leads 62 are only shown as extending away from two (2) sides of the die 32 in FIG. 4.

The present invention provides advantages over current QFP devices. Since the leads do not extend well beyond the sides of the mold compound, the leads are not prone to bending and the device will have a smaller foot print. For the same reason, the width of the leads may be decreased, thus allowing for more leads per row or a higher density of leads. Further, by altering the location of the indentations to allow for two rows of contact points, current design pitch rules can be followed; the pitch is shown at 68 in FIG. 4.

As previously discussed, the present invention also includes a method of assembling a semiconductor device by providing a lead frame having a plurality of leads, each lead having a first end and a second end, wherein the leads extend outwardly from a generally rectangular central space, the first ends being proximate to the central space and the second ends being distal from the central space. Each lead comprises a strip of conductive material having a first downward bend proximate to the first end, a second bend proximate to the second end such that the strip after the second bend is substantially parallel with the strip prior to the first bend, and a micro-indentation between the second bend and the second end, the micro-indentation defining a downwardly projecting dimple.

Next, a semiconductor die having an integrated circuit therein is attached to a flag of the lead frame, if the lead frame has a flag. If the lead frame does not have a flag, the die is typically attached to a tape to which the leads of the lead frame also are attached. The leads are then electrically connected to wire bonding pads of the die via wire bonding and the semiconductor die, the electrical connections and the leads are encapsulated with a mold compound. However, the second ends of the leads protrude from the sides of the mold compound, and a bottom surface of the leads protrudes from a bottom surface of the mold compound at the dimple. The second ends of the leads that protrudes from the mold compound can be trimmed or grinded off.

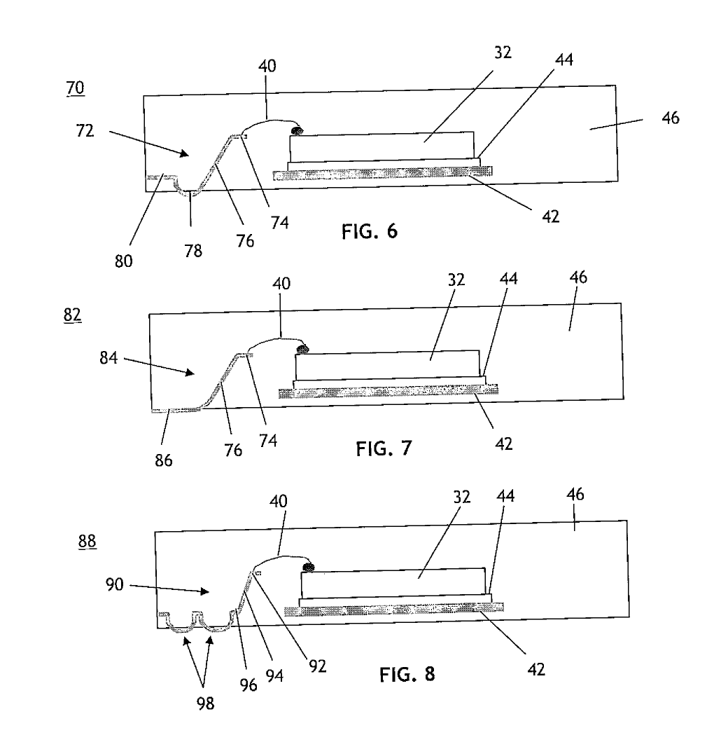

Referring now to FIGS. 6-10, alternative embodiments of a semiconductor device in accordance with the present invention are shown. In each of the alternative embodiments shown, the semiconductor devices include the semiconductor device 32 attached to the flag 42 with epoxy 44, wires 40 connecting wire bonding pads of the die 32 to the lead frame, and a mold compound or encapsulant 46. Each of these elements has been described above and further description is not required for a complete understanding of the invention. Therefore, for the sake of clarity, only the leads of the lead frame for each device will be described. Also, although FIGS. 6-9 show only one lead (on the left side of the drawing), it will be understood by those of skill in the art that the leads may surround the die. That is, just one lead is shown for purposes of clarity.

FIG. 6 is an enlarged cross-sectional side view of a semiconductor device 70. In this embodiment, a lead 72 has a first section 74 that is generally parallel with the die 32 and to which the wire 40 is bonded. A second section 76 angles downwardly and extends from the first section 74 near to a bottom surface of the device 70, where a micro-indentation 78 is formed. The micro-indentation 78 causes the lead 72 to poke through the encapsulant 46 so that the lead is exposed. A third section 80 extends from the micro-indentation to a side of the device 70. In this embodiment, the lead 72 is trimmed so that it does not extend out of the side of the device 70. As should be noted, the lead includes a first bend between the first and second sections 74 and 76, but not a true second bend (like in the embodiment of FIG. 3). That is, in this embodiment, the second bend is integral with the micro-indentation 78.

FIG. 7 is an enlarged cross-sectional side view of a semiconductor device 82. In this embodiment, a lead 84 has a first section 74 that is generally parallel with the die 32 and to which the wire 40 is bonded. A second section 76 angles downwardly and extends from the first section 74 to a bottom surface of the device 70, and then a third section 86 extends from the second section 76 to a side of the device 82. In the third section 86, a bottom surface of the lead 84 lies below the encapsulant 46 and is exposed, and thus provides a means for electrical connection. In this embodiment, there is a bend between the first section 74 and the second section 76, and another bend between the second section 76 and the third section 86. In this embodiment, the lead 84 does not include a micro-indentation. Also in this embodiment, the lead 84 is trimmed so that it does not extend out of the side of the device 82.

FIG. 8 is an enlarged cross-sectional side view of a semiconductor device 88. In this embodiment, a lead 90 has a first section 92 that is generally parallel with the die 32 and to which the wire 40 is bonded. A second section 94 angles downwardly from the first section 92 and extends near to the bottom of the device 88. At the distal end of the second section 94 the lead 90 is bent, as indicated at 96, and then a pair of micro-indentations 98 are formed in the lead 90. The micro-indentations 98 define two downwardly projecting dimples that project beyond the encapsulant 46 to allow for electrical connections thereto. In this embodiment, the lead 90 is trimmed so that it does not extend out of the side of the device 88.

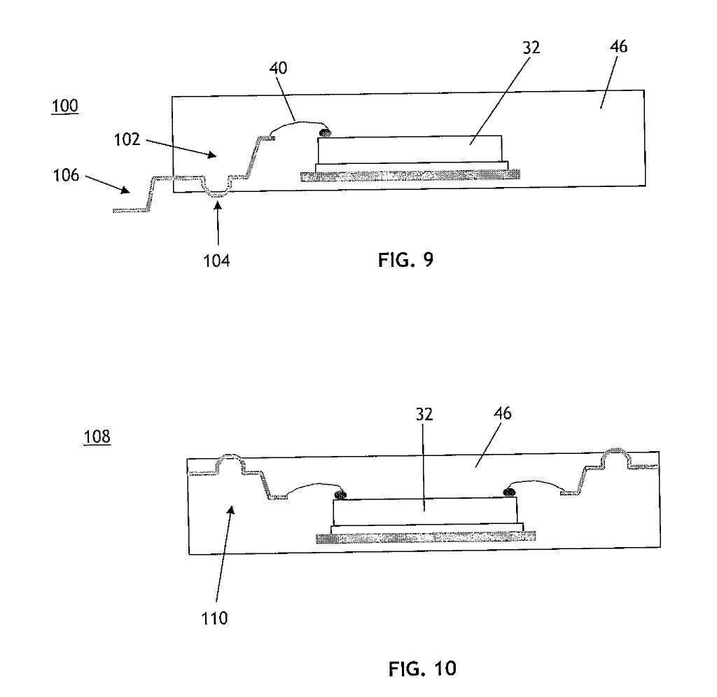

FIG. 9 is an enlarged cross-sectional side view of a semiconductor device 100. In this embodiment, a lead 102 is similar to the lead 34 shown in FIG. 3, including first and second bends and a micro-indentation 104. However, in this embodiment, the lead 102 has not been trimmed. Rather, a section 106 of the lead 102 extends out of the side of the encapsulant 46. As can be seen, the section 106 is angular, like a backwards L-shape, and forms a leg that extends below a bottom surface of the encapsulant 46, thereby providing a stand-off.

FIG. 10 is an enlarged cross-sectional side view of a semiconductor device 108. In this embodiment, a lead 110 is similar to the lead 34 shown in FIG. 3, except that the lead 110 is inversely placed so that a micro-indentation 112 protrudes from a top surface of the encapsulant 46.

While embodiments of the invention have been described and illustrated, it will be understood by those skilled in the technology concerned that many variations or modifications in details of design or construction may be made without departing from the present invention.

1. A semiconductor device, comprising:
a semiconductor die including an integrated circuit formed therein and a plurality of wire bonding pads that allow for connectivity to the integrated circuit;
a lead frame including a plurality of leads, each of the plurality of leads having a first end and a second end;
a plurality of wires electrically connecting respective ones of the wire bonding pads with corresponding ones of the leads at the first ends of the leads; and
a mold compound that encapsulates the die, the leads, and the electrical connections between the leads and the wire bonding pads, wherein the second ends of the leads extend beyond the mold compound such that the second ends of the leads are exposed, and
wherein each lead comprises:
a strip of conductive material having a first downward bend proximate to the first end, a second bend proximate to the second end such that the strip after the second bend is substantially parallel with the strip prior to the first bend, and a micro-indentation between the second bend and the second end, wherein the micro-indentation causes a bottom surface of the lead to be exposed through at least one of the top and bottom surfaces of the mold compound.

2. The semiconductor device of claim 1, wherein the lead frame further comprises a flag and a bottom surface of the die is affixed to the flag.

3. The semiconductor device of claim 1, wherein the micro-indentations on the leads, for alternate leads, is located closer to the second bend such that a pair of rows of the exposed bottom surfaces of the leads is formed at the bottom surface of the mold compound.

4. The semiconductor device of claim 1, wherein two or more micro-indentations are formed between the second bend and the second end of each lead such that each lead is exposed at two locations at the bottom surface of the mold compound.

5. The semiconductor device of claim 1, wherein for each lead, the second bend is integral with the micro-indentation.

6. The semiconductor device of claim 1, wherein the lead frame is formed from a sheet of copper.

7. The semiconductor device of claim 1, wherein the second ends of the leads form legs.

8. The semiconductor device of claim 1, wherein the second ends of the leads are trimmed so that the second ends do not extend beyond the mold compound.

9. The semiconductor device of claim 1, wherein a distance from the first bend to the first end is about 1.0 mm, and a distance from the second bend to the second end is about 3.0 mm.

10. A lead frame for a Quad Flat Pack QFP) type semiconductor device, comprising:
a plurality of leads, each lead having a first end and a second end, wherein the leads extend outwardly from a generally rectangular central space, the first ends being proximate to the central space and the second ends being distal from the central space, and
wherein each lead comprises a strip of conductive material having a first downward bend proximate to the first end, a second bend proximate to the second end such that the strip after the second bend is substantially parallel with the strip prior to the first bend, and at least one micro-indentation between the second bend and the second end, the micro-indentation defining a dimple.

11. The lead frame of claim 10, wherein the lead frame further comprises a flag located in the central space.

12. The lead frame of claim 10, wherein the micro-indentation on the leads, for alternate leads, is located closer to the second bend such that a pair of rows of indentations is formed.

13. The semiconductor device of claim 10, wherein for each lead, the second bend is integral with the micro-indentation.

14. The lead frame of claim 10, wherein the lead frame is formed from a sheet of copper.

15. A method of assembling a semiconductor device, the method comprising:
providing a lead frame having a plurality of leads, each lead having a first end and a second end, wherein the leads extend outwardly from a generally rectangular central space, the first ends being proximate to the central space and the second ends being distal from the central space, and
wherein each lead comprises a strip of conductive material having a first downward bend proximate to the first end, a second bend proximate to the second end such that the strip after the second bend is substantially parallel with the strip prior to the first bend, and a micro-indentation between the second bend and the second end, the micro-indentation defining a downwardly projecting dimple;
placing a semiconductor die having an integrated circuit therein in the central space;
electrically connecting the leads to the integrated circuit; and
encapsulating the semiconductor die, the electrical connections and the leads with a mold compound, wherein the second ends of the leads protrude from the sides of the mold compound and a bottom surface of the leads at the dimple is exposed at a bottom surface of the mold compound.

16. The method of assembling a semiconductor device of claim 15, wherein the lead frame further comprises a flag located in the central area, the method further comprising the step of attaching the die to the flag.

17. The method of assembling a semiconductor device of claim 15, further comprising trimming the second ends of the leads that protrude from the sides of the mold compound.

18. The method of assembling a semiconductor device of claim 15, wherein the micro-indentation on the leads, for alternate leads, is located closer to the second bend such that a pair of rows of dimples is exposed at the bottom surface of the mold compound.

19. The method of assembling a semiconductor device of claim 15, wherein for each lead, the second bend is integral with the micro-indentation.

20. The method of assembling a semiconductor device of claim 15, wherein the second ends of the leads form legs.
